(19) United States
(12) Patent Application Publication
(10) Pub. No.: US 2002/0064223 A1
(43) Pub. Date: May 30, 2002

(54) Method of gray scale generation for displays using a register and a binary weighted clock

(76) Inventor: Jessica L. Stevens, San Mateo, CA (US)

Correspondence Address: Lisa M. Yamonaco, Telegen Corporation, Suite 200, 1840 Gateway Drive, San Mateo, CA, 94404, US

(21) Appl. No.: 09/726,103

(22) Filed: Nov. 29, 2000

(51) Int. Cl. H03K 7/08; G09G 5/10

(52) U.S. Cl. 375/238

(57) ABSTRACT

A circuit and method for generating a pulse width modulated signal. The circuit includes a clock that generates a clock signal having a plurality of clock pulses, the clock pulses being spaced by weighted intervals during a signal period and a register that receives a data word with a plurality of data bits, and that generates a pulse width modulated signal by comparing each data bit to a corresponding one of the clock pulses.

The present invention is related to the following co-pending U.S. patent application Ser. No. ______ entitled “Method of Gray Scale Generation For Displays Using a Binary Weighted Clock;” Ser. No. ______ “Method of Gray Scale Generation For Displays Using a Sample and Hold Circuit With Discharge;” and Ser. No. ______ “Method of Gray Scale Generation For Displays Using a Sample and Hold Circuit With a Variable Reference Voltage.”

### FIELD OF THE INVENTION

The present invention relates to displays and more particularly to driving display pixels according to a gray scale value.

### BACKGROUND OF THE INVENTION

Most displays must support many levels of brightness, i.e. shades of gray or “gray scale”, for each pixel element. With the exception of the cathode ray tube, the cost of gray scale driver electronics is one of the largest component costs of a display system. This is because of the complexity of generating gray scale as well as the fact that there are far more gray scale drivers needed in a display than any other driver element.

For example, in an SVGA Field Emission Display, there are 800 columns, each column composed of 3 sub-columns (Red, Green and Blue) and 600 rows or lines. Each row requires a simple ON or OFF driver, essentially a two level driver, and there are 600 drivers required per display. Each sub-column, however, requires a gray scale driver that may be required to provide 256 or more different levels of brightness, and there are one gray scale driver required per each sub-pixel or 800×3=2,400 of these drivers required per display. Thus, if the row and column drivers cost exactly the same, there would still be a 4:1 ratio of costs due simply to the number of drivers. However gray scale drivers are actually much more expensive than simple two-level drivers since they contain significantly more circuitry and therefore the additional cost would be much greater than 4: 1.

There are two methods of generating the differing levels of pixel brightness in a gray scale driver. The first method is to vary the output voltage or output current provided by the driver. The higher the voltage or current, the brighter the pixel brightness. However, when the brightness is less than maximum, the excess energy that does not go to lighting the pixel is dissipated across the driver, generating heat. This makes the driver expensive because it must dissipate this heat in order to properly operate and few drivers can be packed in one chip because of this heat problem. It is also very complicated and expensive to build a driver which translates digital picture information into the varying output voltages or currents needed for gray scale. Additionally, when the pixel is driven at a low brightness level with reduced voltage or current, the pixel may not be driven at its full efficiency, causing reduced display efficiency and uneven pixel illumination and sharpness.

The second method overcomes these heat and efficiency problems by utilizing the fact that the human eye cannot perceive fast changes in brightness and therefore integrates, or averages, the total light received over time and “sees” an average brightness. In this method, known as Pulse-Width Modulation, the pixel is driven at maximum brightness for a certain period of time and then turned off for another period of time. Because the driver circuit is only fully on or fully off, a minimum amount of the energy is lost in the driver and the pixel is always on at full efficiency. By varying the portion of a cycle that the pixel is lit, the perceived brightness can be varied from barely on to fully on.

However, the circuits to accomplish this second method of gray scale are very complicated. As can be seen in FIG. 1A, a typical gray scale circuit includes a latch or shift register to store the binary gray scale number before it is used, a latch to store the active gray scale number, a counter to generate the time slots, a comparator circuit to determine if the counted number is less than, equal to or greater than the stored gray scale number, and a driver transistor.

In the operation of the circuit shown in FIG. 1A, the binary gray scale number is first stored in the latch or shift register for later transfer to the active latch. After the data is transferred to the active latch, the counter is reset to zero and then begins counting up to a maximum number, which defines one complete brightness cycle, defined as T in FIG. 1B. Each time the counter counts up, its output is compared by the comparator circuit with the gray scale number stored in the active latch. If the stored number in the active latch is lower than the count number from the counter, the comparator circuit will set the driver transistor to ON. When the gray scale number becomes equal to or greater than the count from the counter, the comparator circuit turns the driver transistor to OFF. The period of time when the driver is ON is shown as X in FIG. 1B. The overall brightness of the pixel in the typical gray scale circuit described in FIG. 1A is defined by the ratio of X to T shown in FIG. 1B, where X is defined as the time the driver is ON and T is defined as the total time period for one complete brightness cycle. This solution requires a large amount of circuitry to drive a pixel according to gray scale.

Therefore, there exists a need to reduce the amount of gray scale circuitry to drive a pixel for various types of flat panel displays.

### SUMMARY OF THE INVENTION

The present invention provides a circuit for generating a pulse width modulated signal. The circuit includes a clock that generates a clock signal having a plurality of clock pulses, the clock pulses being spaced by weighted intervals during a signal period and a register for receiving a data word with a plurality of data bits, and that generates a pulse width modulated signal by comparing each data bit to a corresponding one of the clock pulses.

Each data bit is at at least one of a selected or unselected state, and the pulse width modulated signal has an ON portion during the length of time of the clock pulses that when compared has corresponding data bit in the selected state.

In accordance with other aspects of the present invention, the register includes a plurality data latch circuits that shift the data bits through each of the plurality of data latch circuits to a following data latch circuit in accordance with the plurality of clock pulses.

The preferred embodiment of the present invention includes binary weighting the intervals of the clock pulses.

The preferred embodiment of the present invention also includes a latch circuit that latches in a portion of a next data word for a next signal period in the register during at least one of the clock pulses in the present signal period.

In the preferred embodiment of the present invention, the data word represents a gray scale value and a driver circuit that drives a display element according to the generated pulse width modulated signal.

As will be readily appreciated from the foregoing summary, the invention provides an improved circuit for generating a pulse width modulated signal for sending gray scale information to a display.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A and B are diagrams illustrating the prior art;

FIG. 2 is a flow diagram of the present invention;

FIGS. 3 and 4 are diagrams of example clock signals used in the present invention;

FIG. 5 is an example circuit diagram of the present invention;

FIG. 6 is an example of the present invention used with the circuit illustrated in FIG. 5;

FIG. 7 is a circuit diagram of an alternate embodiment of the present invention;

FIG. 8 is an example of the present invention used with the circuit illustrated in FIG. 7; and

FIG. 9 is an illustration of the present invention.

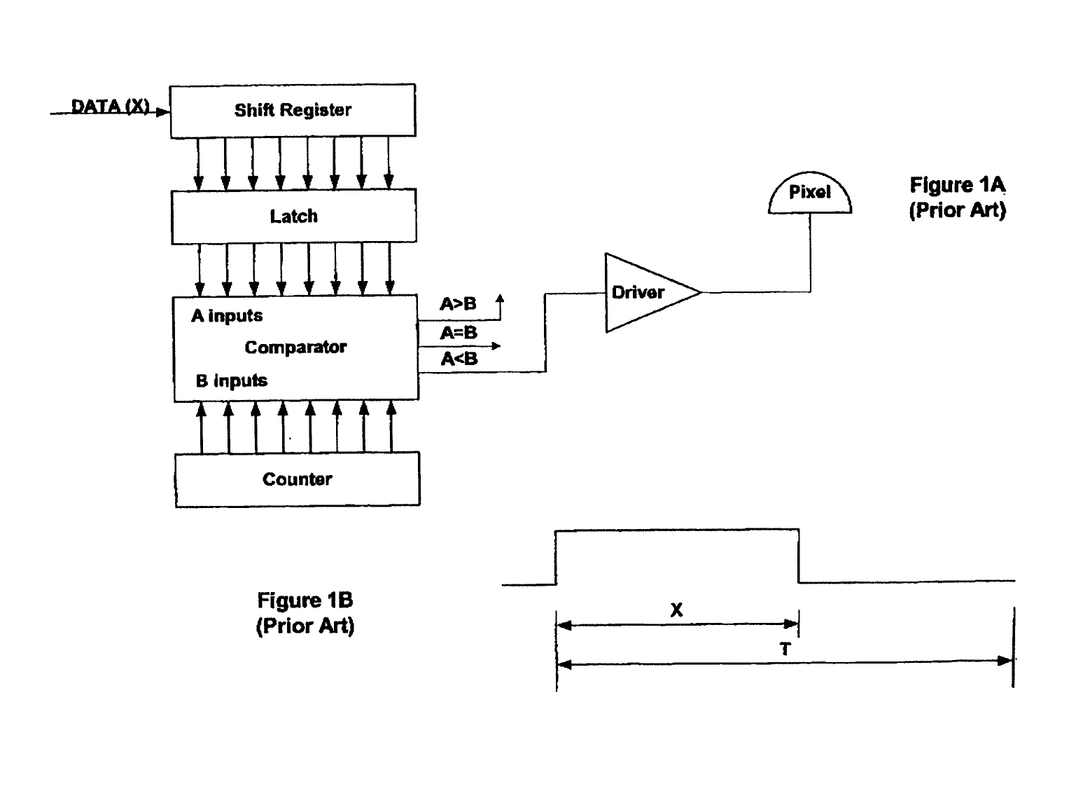

### DETAILED DESCRIPTION OF THE PREFERRED EMBODIMENT

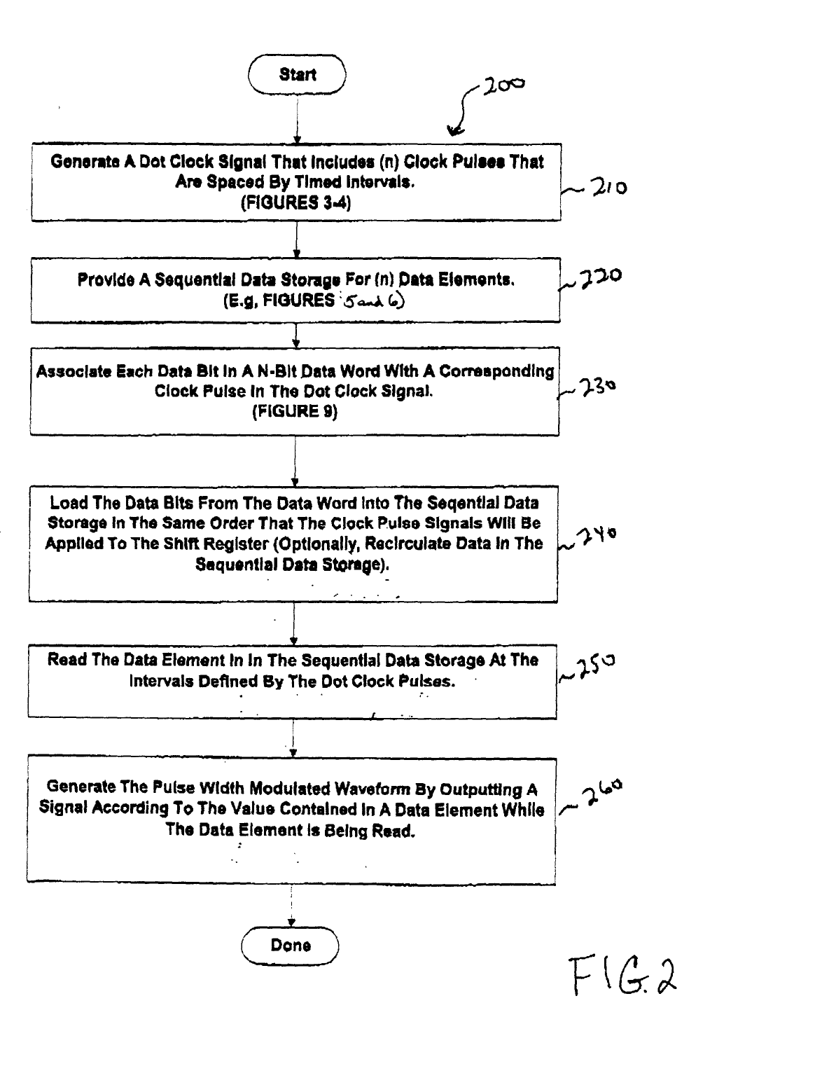

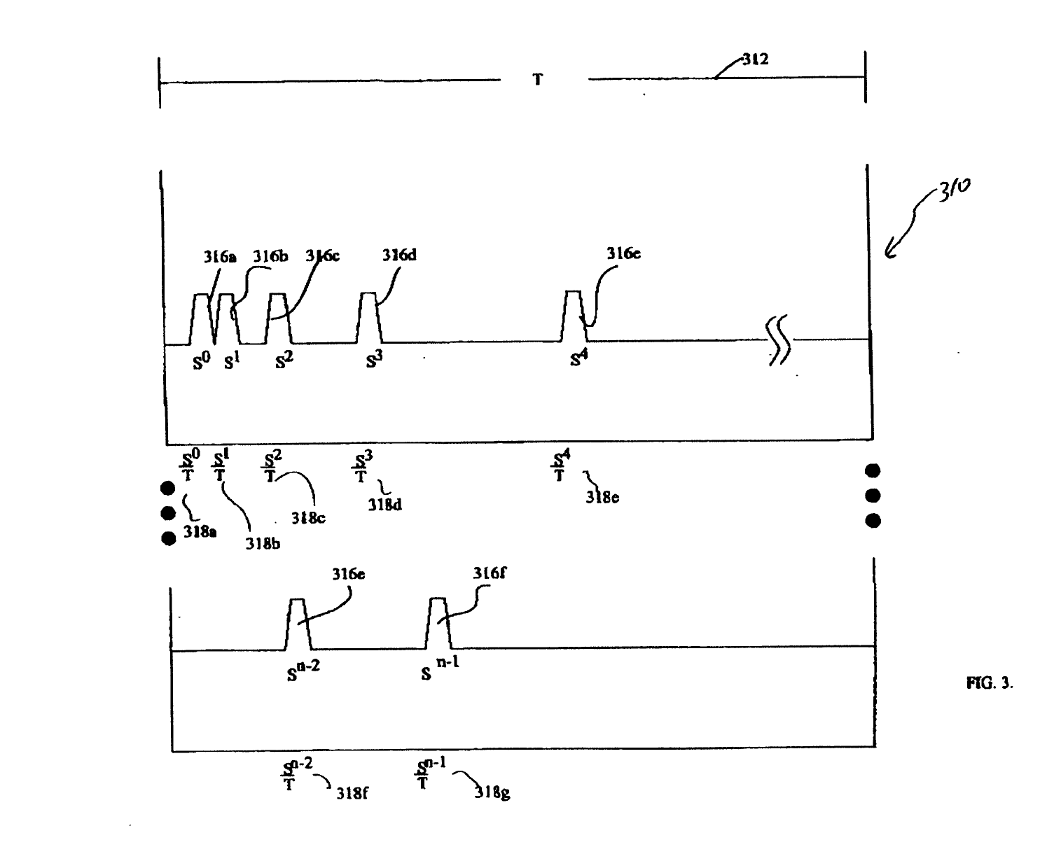

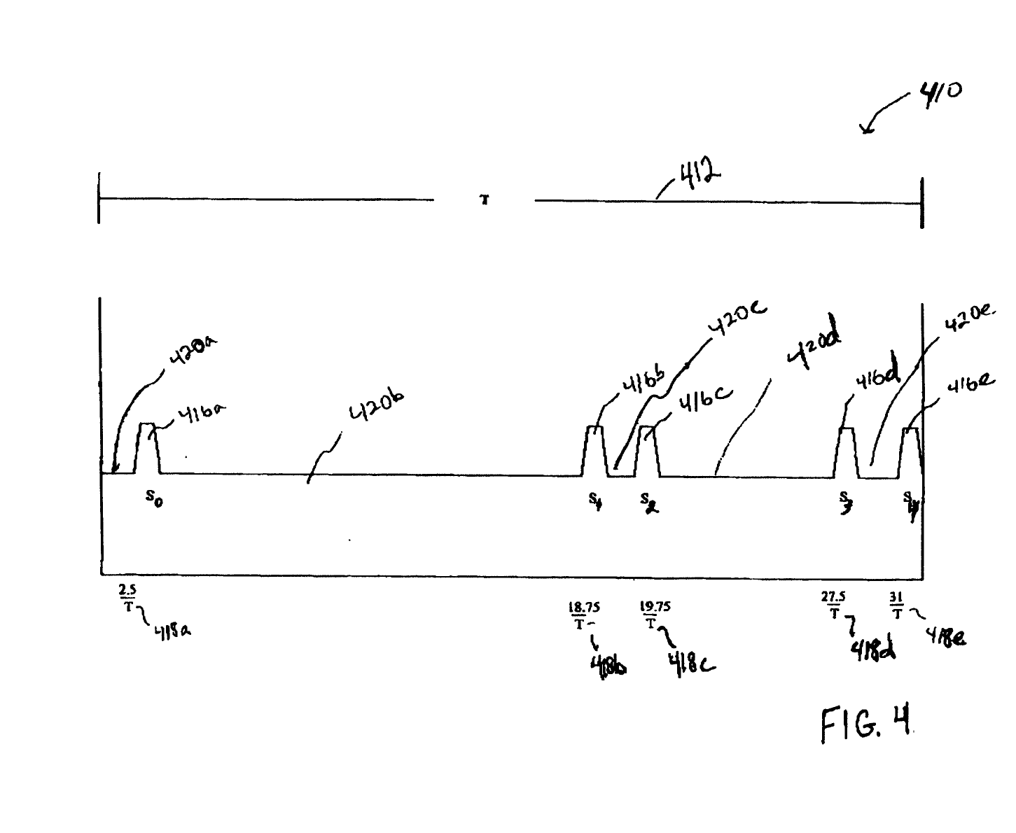

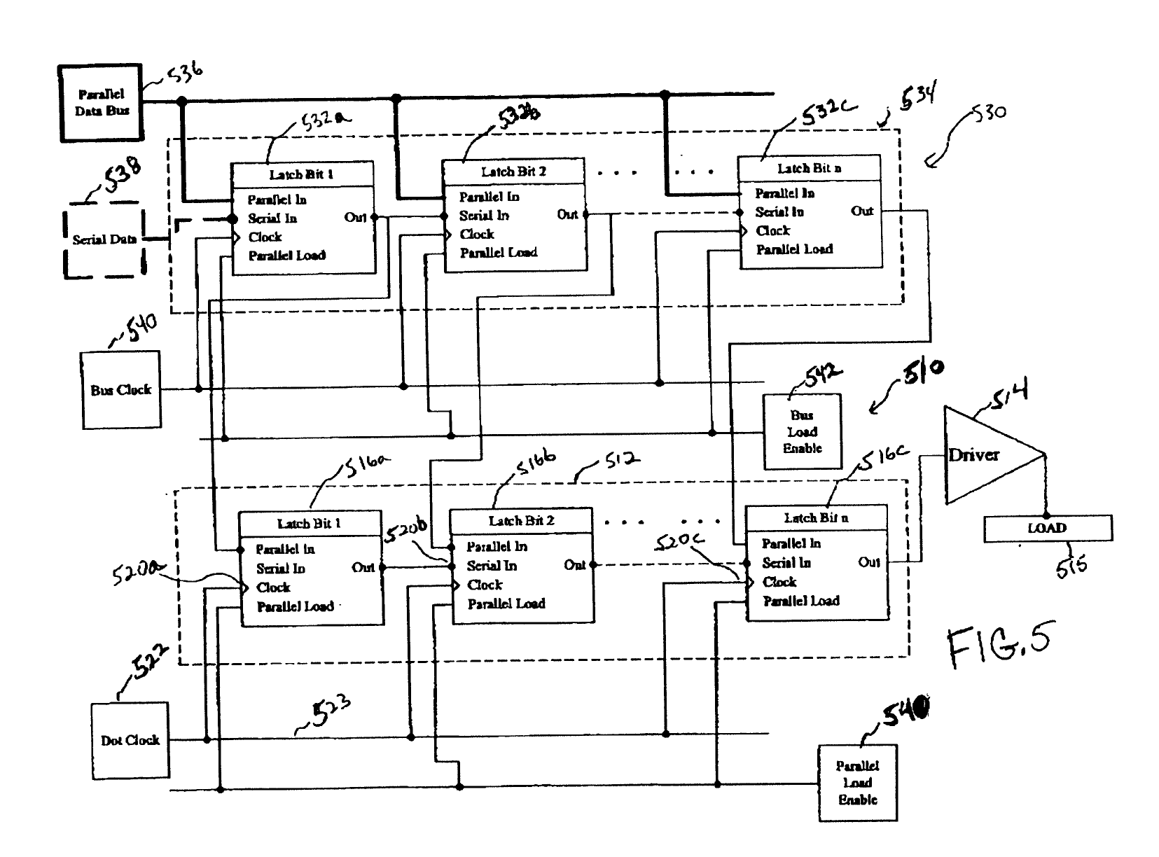

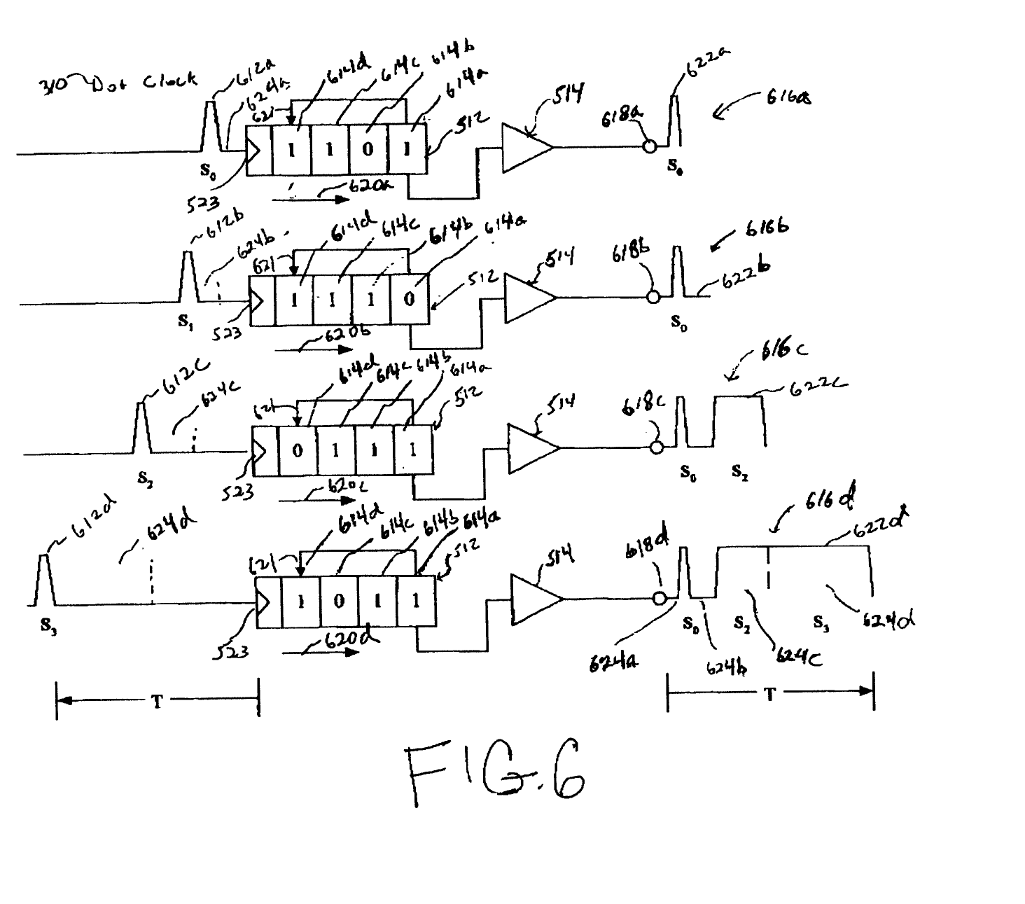

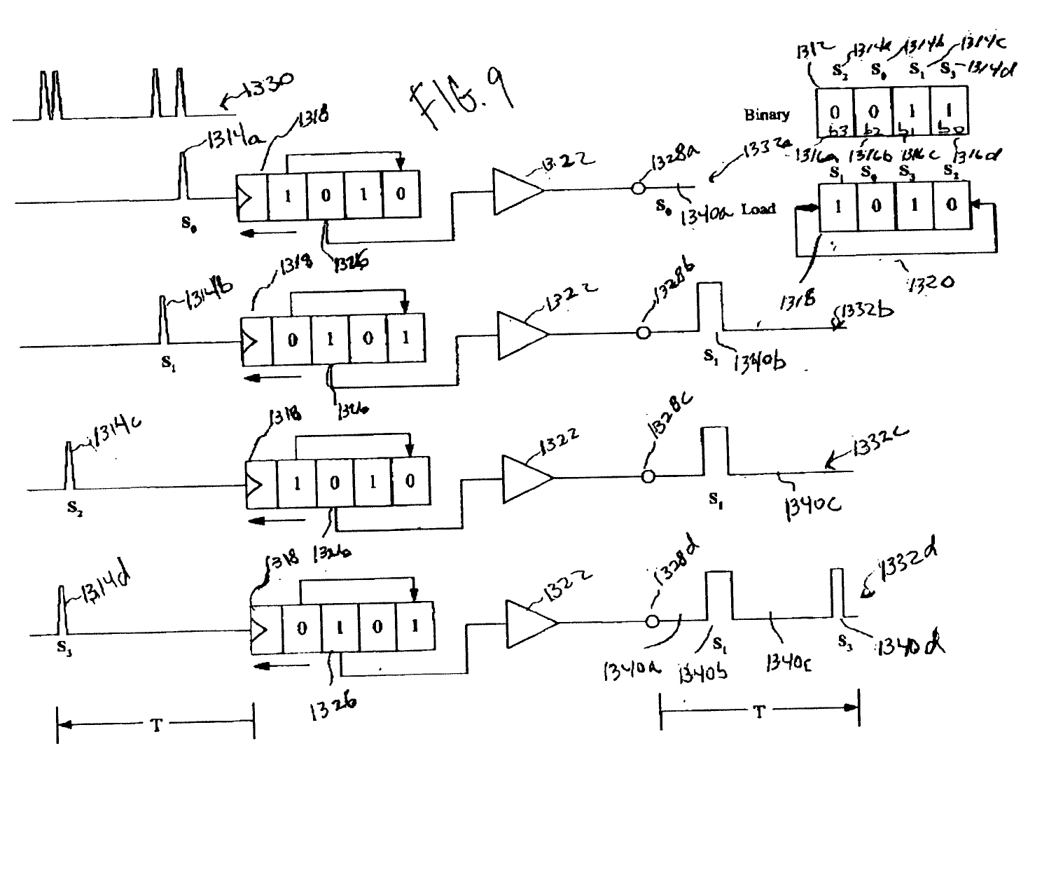

In FIG. 2, a method 200 of the present invention for generating a pulse width modulated signal with a programmable duty cycle is illustrated. The method 200 begins in a block 210 by generating a dot clock signal that includes a number of timed clock pulses. The dot clock signal is discussed in detail below with reference to FIGS. 3 and 4. The method 200 employs a sequential data storage (block 220) that stores data elements that can be read sequentially. Exemplary embodiments of the sequential data storage are described below with reference to FIGS. 5 and 6. In block 230, a duty cycle for a desired pulse width modulated signal is specified by a data word that includes data elements that are associated with the timed clock pulses in the dot clock signal. The associations of the data word with the dot clock signal is discussed below in FIG. 9. The data elements from the data word are loaded into the sequential data storage in a block 240. The data elements are read sequentially according to the timed clock pulses in the dot clock signal in a block 250. The pulse width modulated signal is generated in a block 260 by outputting a signal associated with the data element associated with the first clock pulse in the dot clock signal, then outputting a signal associated with the data element associated with the second clock pulse in the dot clock signal, and so on, until all the data elements have been output.

An exemplary dot clock signal 310 is illustrated in FIG. 3. The dot clock signal includes a number of S pulses that appear at defined intervals during the dot clock signal. In a preferred embodiment, the dot clock signal has a plurality of S pulses spaced in the dot clock signal according to a binary weighting formula. As discussed below, however, there are other ways to position the S pulses in the dot clock signal while remaining within the scope and spirit of the invention.

In FIG. 3, the dot clock signal 310 has a number (n) of S pulses 316a-f that occur during a total period (T) 312. The number (n) of S pulses is theoretically unlimited, but is generally decided by the resolution requirements for controlling the duty cycle of the output PWM signal for reasons discussed below. Each S pulse 316a-g has its own unique place in time 318a-g during the period T 312. For example, in FIG. 3, S pulse s⁰ 310a occurs at time period s⁰/T 318a, S pulse s¹ 310b occurs at time period s¹/T 318b, S pulse s² 310c occurs at time period s₂/T 318c, S pulse s³ 310d occurs at time period s/T 318d, S pulse s₄ 310e occurs at time period s⁴/T 318e, S pulse s⁵ 310e occurs at time period s⁵/T 318e, and so on, until the last two S pulses in the series are positioned with S pulse sⁿ⁻² 310f occurring at time period sₙ₋₂/T 318f and S pulse sⁿ⁻¹ 310g occurring at time period sⁿ⁻¹/T 318g. For example, if the S pulses are binary weighted (s=2), signal s⁵ would occur at time 2⁵ /T.

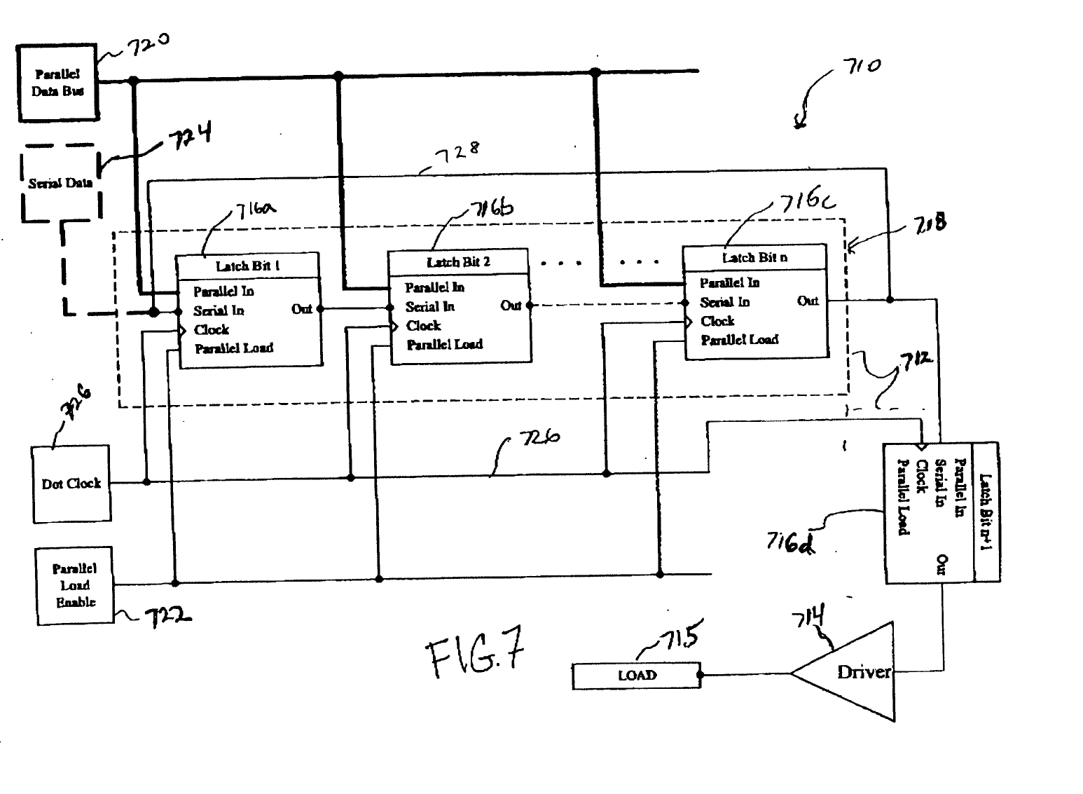

The duration of the S pulses 316a-f is sufficient to activate a shift input of a sequential data storage such as is described below in FIGS. 5 and 7. Either the leading or following edge of the S pulse may be used to activate the shift input and the S pulse positioned to correspond with the time period 318a-f accordingly. The S pulses may also be implemented in software, for instance, with the S pulses 316a-f representing software timer interrupts.

While binary weighting of the dot clock signal has certain advantages in digital applications (discussed below with reference to FIG. 5), the S pulses 316a-f do not have to be placed sequentially at time periods 318a-f according to a weight value, but may be reordered in any pattern desired. Referring to FIG. 4, one of many possible alternate dot clock signals 410 is illustrated. The dot clock signal 410 has five S pulses 416a-e that appear during a total period, or S-cycle (T) 412, at time periods 418a-e, respectively. As will become apparent in the discussion below, the intervals 420a-e between the S pulses 416a-e define the length of respective power supplying pulses in an output pulse width modulated (PWM) signal. The choice of the length of these intervals may affect the resolution and accuracy available in generating the output pulse width modulated signal but there may be many possible dot clock signals that would supply an output PWM signal within the tolerance of any given load. In the example dot clock signal 410, S pulse s₀ 416a occurs at time period (2.5/T) 418a and has an interval 420a from the start of the S cycle 412 of 2.5/T. S pulse s₁ 416b occurs at time period (18.75/T) 418b and has an interval 420b from S pulse s₀ 416a of 16.25/T. S pulse s₂ 416c occurs at time period (19.75/T) 418c and has an interval 420c from S pulse s₁ 416b of 1/T. S pulse s₃ 416d occurs at time period (27.5/T) 418d and has an interval 420d from S pulse s₂ 416c of 7.75/T. S pulse s₄ 416e occurs at time period (31/T) 418e and has an interval 420e from S pulse s₃ 416d of 3.5/T.

An embodiment of a programmable pulse width modulated signal generator 510 is illustrated in FIG. 5. The pulse width modulated generator 510 includes a sequential data storage (shift register) 512 and a driver 514. The driver 514 supplies a pulse width modulated power signal to a load 515. The sequential data storage includes a plurality data latch circuits 516a-c (such as D flip flops) connected together as a shift register. Generally, there will be a data latch circuit 516a-c for each data element in a data word that specifies a desired duty cycle for the pulse width modulated signal to be generated. A shift input (often referred to as a clock input) 520a-c of each data latch circuit 516a-c ais coupled to a dot clock signal (e.g., FIGS. 3-4).

One use for the pulse width modulated signal generator 510 is to drive the gray scale of a pixel element in a display using a pulse width modulated signal. Because of timing constraints in this usage, it is desirable to pre-load a next data word for a next gray scale value as the current gray scale value is being generated using a current data word. A pre-load latch circuit 530 is provided for this purpose. The pre-load latch circuit 530 includes a plurality of latch circuits 532a-c, with a latch circuit 532a-c provided for each data element in the data word. The data latch circuits 532a-c may be independent or configured as a shift register 534 to receive the data word either from a parallel data bus 536 or a serial data line 538. The data word may be clocked into the shift register 534 using a parallel load enable signal or bus clock 540 that is coupled to each data latch circuit 532a-c or loaded in parallel when a bus load enable signal 542 that is also coupled to each data latch circuit 532a-c is activated.

An output of each of the data latch circuits 532a-c in the pre-load latch circuit 530 is coupled to an input of a corresponding data latch circuit 516a-c in the pulse width modulated generator 510. In operation, a current data word is processed in the pulse width modulated signal generator 510, as is described below with reference to FIG. 6. While the current data word is being processed, a next data word is loaded into the pre-load latch circuit 530 from the parallel data bus 536 when the bus load enable 542 is activated (or from the serial data line 538 as the parallel load enable signal 540 clocks the data into the shift register 534. The next data word, now stored in the shift register 534, is loaded into the pulse width modulated generator 510 and is activated to be processed as the then current data word when a parallel load enable signal 540 is activated. A new next data word is then loaded from the parallel data bus 536 into the pre-load circuit 530 and the process repeats.

The operation of the pulse width modulation generator 510 is illustrated in FIG. 6. To simplify the following discussion, the first four S pulses (316a-d) from the dot clock signal 310 (FIG. 3) are shown separately as S pulses 612a-d as they “enter” the shift input 523 of the shift register 512. A resulting (cumulative) PWM signal 616a-d is shown following each S pulse 612a-d at a driver output 618a-d. The shift register 512 in this example has four data latch circuits 614a-d that are loaded with data elements “1101” from sample current data word. As discussed below, this data word may be coded in any convenient way, which in this example we will assume is a binary word. The data word “1101” equals a decimal 13 out of a possible 16 values (2⁴) or a duty cycle of 13/16.

Each data element in the data word is associated with an S pulse 612a-d. The data latch circuits 614a-d are also associated with the S pulses 612a-d in a shift order that corresponds with the arrival of the S pulses 612a-d. The data elements (b₃,b₂,b₀) in the data word are loaded into their corresponding data latch circuits 614a-d according to their associated S pulses 612a-d. In FIG. 6, data latch circuit 614a is associated with S pulse s₀ 612a and loaded with b₀=1, data latch circuit 614b is associated with S pulse s₁ 612b and loaded with b₁=0, data latch circuit 614c is associated with S pulse s₂ 612c and loaded with b₂=1, and data latch circuit 614d is associated with S pulse s₃ 612d and loaded with b₃=1. The driver 514 outputs the PWM signal based on a state of the data latch 614a associated with the first S pulse s₀ 612a.

The generation of the PWM signal 616a-d is illustrated in FIG. 6 as a progression through four states 620a-d of the shift register 512. The shift register 512 is configured in this example to preserve the data word by re-circulating the data elements in the shift register as they are shifted, as indicated by arrow 621. In the first state 620a of the shift register 512, the data latch 614a has a state “1” and the driver 514 takes the output 618a HIGH until the arrival of the so pulse 612a. This results in a PWM pulse 622a with a duration nearly equal to an interval 624a from the beginning of the S cycle until the arrival of the S pulse s₀ 612a. The S pulse s₀ 612a defines the length of the PWM pulse 622a by causing the shift register 512 to shift the data elements, which in the next state 620b, places the data elements “1110” into the data latch circuits 614d, 614c, 614b and 614a, respectively.

In the second state 620b of the shift register 512, the data latch 614a has a state “0” and the driver 514 takes the output 618b LOW until the arrival of the s₁ pulse 612b. This results in a LOW PWM pulse 622b (shown at zero) with a duration nearly equal to an interval 624b from the arrival of the S pulse s₀ 612a until the arrival of the S pulse s₁ 612b. The S pulse s₁ 612b defines the length of the PWM pulse 622b by causing the shift register 512 to shift the data elements, which in the next state 620c, places the data elements “0111” into the data latch circuits 614d, 614c, 614b and 614, respectively.

In the third state 620c of the shift register 512, the data latch 614a has a state “1” and the driver 514 takes the output 618c HIGH until the arrival of the s₂ pulse 612c. This results in a HIGH PWM pulse 622c with a duration nearly equal to an interval 624c from the arrival of the S pulse s₀ 612b until the arrival of the S pulse s₂ 612c. The S pulse s₂ 612c defines the length of the PWM pulse 622c by causing the shift register 512 to shift the data elements, which in the next state 620d, places the data elements “1011” into the data latch circuits 614d, 614c, 614b and 614, respectively.

In the fourth state 620d of the shift register 512, the data latch 614a has a state “1” and the driver 514 takes the output 618d HIGH until the arrival of the s₃ pulse 612d. This results in a HIGH PWM pulse 622d with a duration nearly equal to an interval 624d from the arrival of the S pulse s₂ 612c until the arrival of the S pulse s₃ 612d. The S pulse s₃ 612d defines the length of the PWM pulse 622d by causing the shift register 512 to shift the data elements, which in the next state 620d, places the data elements “1101” into the data latch circuits 614d, 614c, 614b and 614, respectively. Following the fourth state 620d, the current S cycle is concluded and the next S cycle begins. A new data word can be loaded into the shift register 512 for the next S cycle, or the data word that is currently in the shift register 512 can be reused.

Another embodiment of a programmable pulse width modulated generator 710 is illustrated in FIG. 7. The pulse width modulated generator 710 includes a sequential data storage 712 and a driver 714. The driver supplies a pulse width modulated power signal to a load 715, which is the preferred embodiment is a pixel in a display. The sequential data storage includes a plurality data latch circuits 716a-c (such as D flip flops) connected together as a shift register 718. Generally, there will be a data latch circuit 716a-c for each data element in a data word that specifies a desired duty cycle for the pulse width modulated signal to be generated.

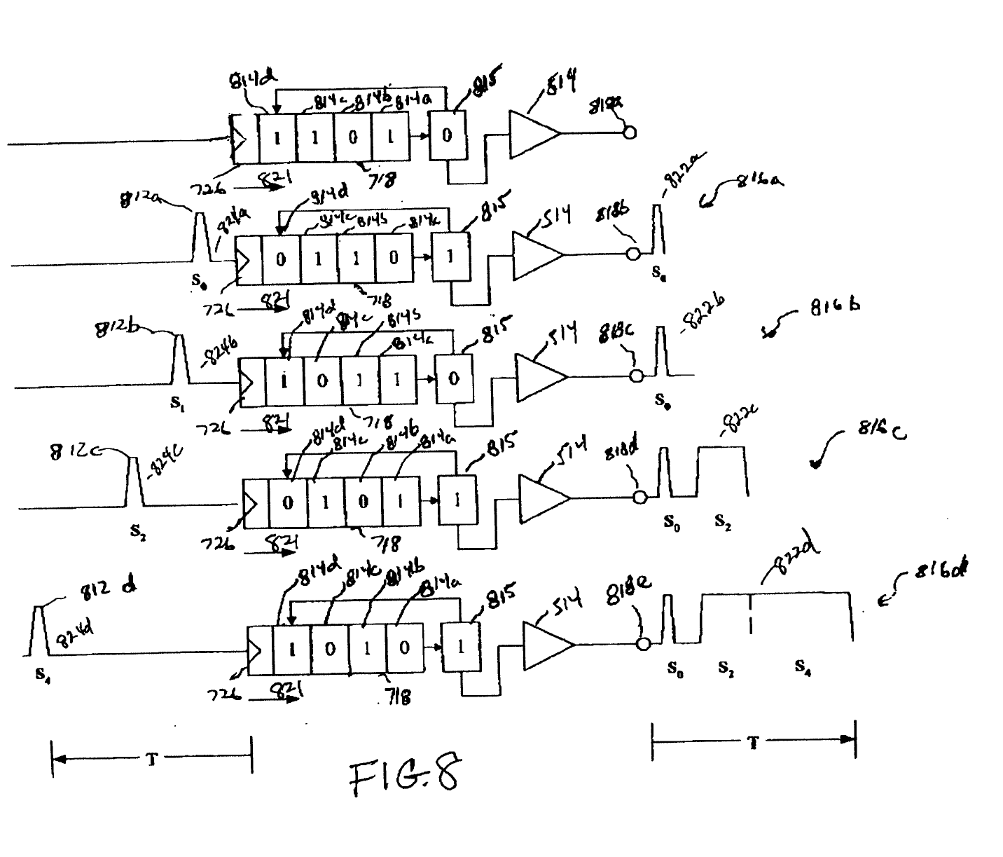

The data word is preferably loaded into the data latch circuits 716a-c through a parallel data bus 720 when activated by a parallel load enable 722. The data word may alternatively be loaded from a serial data connection 724 into the shift register 718 by activating a common shift input. An additional data latch 716d is connected in series with data latches 716a-c. As will be discussed in detail below with reference to FIG. 8, the additional data latch 716d provides storage for the processing of one or more data elements in a data word while a next data word is being loaded into the shift register 718. A dot clock 726 (FIGS. 3-4) is coupled to the shift input. To facilitate the reuse the data word over more than one S cycle, a feedback loop 728 couples an output to an input of the shift register 718 (the output of the data latch circuit 716c to the serial input of the first 716a data latch circuit). Data latch circuit 716d may also be included in the re-circulation of the data word, as is discussed below in FIG. 8.

The operation of the pulse width modulation generator 710 is illustrated in FIG. 8. As in the discussion of FIG. 8, the first four S pulses (316a-d) from the dot clock signal 310 (FIG. 3) are shown separately as S pulses 812a-d as they “enter” the shift input of the shift register 718. A resulting (cumulative) PWM signal 816a-d is shown following each S pulse 812a-d at a driver output 818a-d. The shift register 718 in this example has four data latch circuits 814a-d that are loaded with data elements “1101” from sample current data word. As discussed below, this data word may be coded in any convenient way, which in this example we will assume is a binary word. The data word “1101” equals a decimal 13 out of a possible 16 values (24) or a duty cycle of 13/16.

Each data element in the data word is associated with an S pulse 812a-d. The data latch circuits 814a-d are also associated with the S pulses 812a-d in a shift order that corresponds with the arrival of the S pulses 812a-d. The data elements (b3,b2,b1,b0) in the data word are loaded into their corresponding data latch circuits 814a-d according to their associated S pulses 812a-d. In FIG. 8, data latch circuit 814a is associated with S pulse s0 812a and loaded with b0=1, data latch circuit 814b is associated with S pulse s1 812b and loaded with b1=0, data latch circuit 814c is associated with S pulse s2 812c and loaded with b2=1, and data latch circuit 814d is associated with S pulse s3 812d and loaded with b3=1. The driver 514 outputs the PWM signal based on a state of the data latch 814a associated with the first S pulse s0 812a.

The generation of the PWM signal 816a-d is illustrated in FIG. 8 as a progression through four states of the shift register 718. The shift register 718 is configured in this example to preserve the data word by re-circulating the data elements in the shift register as they are shifted, as indicated by arrow 821. In the first state of the shift register 718, the data latch 814a has a state “1” and the driver 514 takes the output 818a HIGH until the arrival of the s0 pulse 812a. This results in a PWM pulse 822a with a duration nearly equal to an interval 824a from the beginning of the S cycle until the arrival of the S pulse s0 812a. The S pulse s0 812a defines the length of the PWM pulse 822a by causing the shift register 718 to shift the data elements, which in the next state 820b, places the data elements “1110” into the data latch circuits 814d, 814c, 814b and 814a, respectively.

In the second state of the shift register 718, the data latch 814a has a state “0 ” and the driver 514 takes the output 818b LOW until the arrival of the s1 pulse 812b. This results in a LOW PWM pulse 822b (shown at zero) with a duration nearly equal to an interval 824b from the arrival of the S pulse s0 812a until the arrival of the S pulse s1 812b. The S pulse s1 812b defines the length of the PWM pulse 822b by causing the shift register 718 to shift the data elements, which in the next state, places the data elements “0111” into the data latch circuits 814d, 814c, 814b and 814a, respectively.

In the third state of the shift register 718, the data latch 814a has a state “1” and the driver 514 takes the output 818c HIGH until the arrival of the s2 pulse 812c. This results in a HIGH PWM pulse 822c with a duration nearly equal to an interval 824c from the arrival of the S pulse s1 812b until the arrival of the S pulse s2 812c. The S pulse s2 812c defines the length of the PWM pulse 822c by causing the shift register 718 to shift the data elements, which in the next state, places the data elements “1011” into the data latch circuits 814d, 814c, 814b and 814a, respectively.

In the fourth state of the shift register 718, the data latch 814a has a state “1” and the driver 514 takes the output 818d HIGH until the arrival of the s3 pulse 812d. This results in a HIGH PWM pulse 822d with a duration nearly equal to an interval 824d from the arrival of the S pulse s2 812c until the arrival of the S pulse s3 812d. The S pulse s3 812d defines the length of the PWM pulse 822d by causing the shift register 718 to shift the data elements, which in the next state 820d, places the data elements “1101” into the data latch circuits 814d, 814c, 814b and 814a, respectively. Following the fourth state, the current S cycle is concluded and the next S cycle begins. A new data word can be loaded into the shift register 718 for the next S cycle, or the data word that is currently in the shift register 718 can be reused.

The preceding examples have assumed a binary data word that is loaded into a standard shift register that are shifted according to a binary weighted dot clock signal to an shift register output with a least significant bit appearing in the output first and a most significant bit appearing in the output last. As was discussed above with reference to FIGS. 4A and B, the dot clock signal does not have to binary weighted. Similarly, there are many modification that may be made to the above examples that remain within the spirit and scope of the invention. For instance, a data word 1312 may be mapped to a set of S pulses 1314a-d in an order. In FIG. 9, S pulse s₂ 1314a is mapped to b₃ 1316a, S pulse s₀ 1314b is mapped to b₂ 1316b, S pulse s₁ 1314c is mapped to b₁ 1316c, and S pulse s₃ 1314d is mapped to b₀ 1316d.

The data elements 1316a-d in the data word 1312 are loaded into a shift register in the sequential order that the S pulses are input to the shift register 1318. In FIG. 9, the shift register 1318 is configured to shift from right to left (arrow 1320). A diver 1322 is coupled to a data storage circuit 1326 that is associated with the first S pulse to arrive at the shift register input. In the example illustrated in FIG. 9, the binary equivalent of the data word is “0011 ”, which when considering the mapping just described indicates a duty cycle of 3/16. Using a dot clock signal 1330, that is broken into pulses 1314a-d in the illustration, a PWM signal 1332a-d is generated in much the same manner that is described above in FIGS. 6 and 8.

In the example, the data storage circuit 1326 contains the initially loaded value “0”, which causes the driver to output a LOW PWM pulse 1340a until the so pulse 1314a is input to the shift register 1318. The s₀ pulse shifts the data elements to the left, entering a “1” in the data storage circuit 1326, which causes the driver 1322 to output a HIGH PWM pulse 1340b until the s₁ pulse 1314b is input to the shift register 1318. The s₁ pulse shifts the data elements to the left, entering a “0” in the data storage circuit 1326, which causes the driver 1322 to output a LOW PWM pulse 1340c until the s₂ pulse 1314c is input to the shift register 1318. The s₂ pulse shifts the data elements to the left, entering a “1” in the data storage circuit 1326, which causes the driver 1322 to output a HIGH PWM pulse 1340d until the s₃ pulse 1314b is input to the shift register 1318. The s3 pulse shifts the data back to the original order of the data word, which may be used again or a new data word loaded, as discussed above. As the PWM signal 1340d illustrates, the timing of the S pulses 1314a-d together with the order and shifting of the data word in the shift register 1318 yield a PWM signal with a duty cycle of 3/16, as specified in the data word 1312.

While the preferred embodiment of the invention has been illustrated and described, many changes can be made without departing from the spirit and scope of the invention. Accordingly, the scope of the invention is not limited by the disclosure of the preferred embodiment. Instead, the invention should be determined entirely by reference to the claims that follow.

The embodiments of the invention in which an exclusive property or privilege is claimed are defined as follows:

I claim:

1. A programmable pulse width modulation generator circuit for generating a pulse width modulated signal, the circuit comprising:
a clock for generating a clock signal having a plurality of clock pulses, the clock pulses being spaced by weighted intervals during a signal period; and
a register for receiving a data word with a plurality of data bits, and for generating a pulse width modulated signal by comparing each data bit to a corresponding one of the clock pulses.

2. The programmable pulse width modulation generator circuit of claim 1, wherein each data bit is at at least one of a selected or unselected state, and
wherein the pulse width modulated signal has an ON portion during the length of time of the clock pulses that when compared has corresponding data bit in the selected state.

3. The programmable pulse width modulation generator circuit of claim 1, wherein the register comprises a plurality data latch circuits for shifting the data bits through each of the plurality of data latch circuits to a following data latch circuit in accordance with the plurality of clock pulses.

4. The programmable pulse width modulation generator circuit of claim 1, wherein the weighted intervals are binary.

5. The programmable pulse width modulation generator circuit of claim 1, further comprising:
a latch circuit for latching in a portion of a next data word for a next signal period in the register during at least one of the clock pulses in the present signal period.

6. The pulse width modulation generator circuit of claim 1, wherein the data word represents a gray scale value.

7. The pulse width modulation generator circuit of claim 6, further comprising:
a driver circuit for driving a display element according to the generated pulse width modulated signal.

8. A method for generating a pulse width modulated signal, the method comprising:
generating a clock signal having a plurality of clock pulses, the clock pulses being spaced by weighted intervals during a signal period; and
receiving a data word with a plurality of data bits; and
generating a pulse width modulated signal by comparing each data bit to a corresponding one of the clock pulses.

9. The method of claim 8, wherein each data bit is at at least one of a selected or unselected state, and
wherein the pulse width modulated signal has an ON portion during the length of time of the clock pulses that when compared has corresponding data bit in the selected state.

10. The method of claim 8, wherein generating comprises shifting the data bits through each of a plurality of data latch circuits to a following data latch circuit in accordance with the plurality of clock pulses.

11. The method of claim 8, wherein the weighted intervals are binary.

12. The method of claim 8, further comprising:
latching in a portion of a next data word for a next signal period in the register during at least one of the clock pulses in the present signal period.

13. The method of claim 8, wherein the data word represents a gray scale value.

14. The method of claim 13, further comprising:
driving a display element according to the generated pulse width modulated signal.
